(19) United States
(12) Patent Application Publication
(10) Pub. No.: US 2013/0340817 A1
(43) Pub. Date: Dec. 26, 2013

(54) THIN FILM SILICON SOLAR CELL IN TANDEM JUNCTION CONFIGURATION ON TEXTURED GLASS

(71) Applicants: Julien Bailat, Biel/Bienne (CH); Karl William Koch, III, Elmira, NY (US); Glenn Eric Kohnke, Corning, NY (US); Sasha Marjanovic, Painted Post, NY (US); Johannes Meier, Corcelles (CH)

(72) Inventors: Julien Bailat, Biel/Bienne (CH); Karl William Koch, III, Elmira, NY (US); Glenn Eric Kohnke, Corning, NY (US); Sasha Marjanovic, Painted Post, NY (US); Johannes Meier, Corcelles (CH)

(73) Assignees: OERLIKON SOLAR AG, TRUBBACH, Trubbach (CH); CORNING INCORPORATED, Corning, NY (US)

(21) Appl. No.: 13/819,045

(22) PCT Filed: Sep. 1, 2011
(86) PCT No.: PCT/US2011/050182

§ 371 Date: Sep. 6, 2013

Related U.S. Application Data
(60) Provisional application No. 61/379,844, filed on Sep. 3, 2010.

(51) Int. Cl. H01L 31/0236; H01L 31/076

(52) U.S. Cl. CPC H01L 31/0236; H01L 31/076
USPC 136/255; 136/256

(57) ABSTRACT

Solar cells or solar modules of the so-called tandem type, i.e. stacked arrangements of photovoltaic absorber devices on a substrate with a textured surface are described. The thin film solar cell has a substrate comprising a textured surface, and a front electrode layer comprising a transparent conductive oxide adjacent to the textured surface, wherein the electrode layer has a thickness less than the roughness of the textured surface.

This application claims the benefit of priority under 35 U.S.C. §119 of U.S. Provisional Application No. 61/379,844 filled on Sep. 3, 2010 the contents of which is relied upon and incorporated herein by reference in its entirety.

### BACKGROUND

1. Field

Embodiments relate generally to solar cells or solar modules of the so-called multi-junction type, for example, silicon tandem, i.e. stacked arrangements of photovoltaic absorber devices on a substrate with a textured surface.

2. Technical Background

FIG. 1 is an illustration of a tandem-junction silicon thin film solar cell as known in the art. Such a thin film solar cell 100 usually includes a first or front electrode 12, one or more semiconductor thin film p-i-n junctions (top cell 30 having layers 14, 16, and 18, and bottom cell 32, having layers 20, 22, and), and a second or back electrode 26, which are successively stacked on a substrate 10. Each p-i-n junction 30, 32 or thin-film photoelectric conversion unit includes an i-type layer 16, 22 sandwiched between a p-type layer 14, 20 and an n-type layer 18, 24 (p-type=positively doped, n-type=negatively doped). The p-type and n-type layers can be amorphous or microcrystalline. Substantially intrinsic in this context is understood as undoped or exhibiting essentially no resultant doping. Photoelectric conversion occurs primarily in this i-type layer; it is therefore also called absorber layer. A back reflector 28 is typically included on the back electrode.

Depending on the crystalline fraction (crystallinity) of the i-type layer 16, 22 solar cells or photoelectric (conversion) devices are characterized as amorphous (a-Si, 16) or microcrystalline (μc-Si, 22) solar cells, independent of the kind of crystallinity of the adjacent p and n-layers. Microcrystalline layers are being understood, as common in the art, as layers comprising of a significant fraction of crystalline silicon—so called micro-crystallites—in an amorphous matrix. Stacks of p-i-n junctions are called tandem or triple junction photovoltaic cells. The combination of an amorphous and microcrystalline p-i-n-junction, as shown in FIG. 1, is also called a micromorph tandem cell. Light, arrows 34 is typically incident from the side of the deposition substrate such that the substrate becomes a superstrate in the cell configuration.

A plasma-enhanced chemical vapor deposition (PECVD) deposition system as known in the art is schematically shown in FIG. 2. Basically, a PECVD reactor 200 comprises two metallic electrodes 36, 38 with an outer surface 36a, 38a, respectively. The electrodes are arranged spaced apart from each other in planes essentially parallel to each other. A gas source (not shown) provides the reactor 200 with a reactive gas (or a gas mixture) based on which plasma is generated by means of a radiofrequency discharge. Known pumping means can be used for evacuating exhaust gases via outlets (omitted in FIG. 2). The radiofrequency discharge is generated by at least one radiofrequency source 40 connected to one of the electrodes, here electrode 36. The other electrode 38 is grounded as shown in FIG. 2. This electrical scheme can vary and is not intended to be limiting.

The plasma can be observed in the internal process space 42 which extends between the electrodes 36 and 38. A substrate 11 can be arranged on one of the electrodes, in FIG. 2 on the lower electrode 38. The substrate 11 can be a dielectric plate of a substantially uniform thickness which defines the lower limit of the internal process space 42 during operation of the PECVD reactor 200, so that the substrate 11 is exposed to the processing action of the plasma discharge. The distance between the facing surfaces of the substrate 11 and electrode 36 is labelled d; during operation the surfaces are facing the plasma.

Most of the layers responsible for the photoelectric effect in solar cells/modules are deposited in PECVD systems. A very common application is the deposition of doped and undoped layers of silicon and silicon compounds of certain crystallinity.

“Grid-parity” marks the borderline for so called alternative energy generation, from which point on such alternative energy generation is regarded fully competitive with conventionally generated energy. This shall be achieved by enhancing the overall efficiency of the solar cells, which further allows reducing the installation cost of solar power systems.

An important step ahead for thin-film silicon technology was achieved by making the so called thin-film tandem junction cell industrially viable. Based on the works of Johannes Meier and Ulrich Kroll at the University of Neuchatel, Switzerland in the mid 1990ies the combination of an pin-junction based on amorphous silicon and a further pin-junction based on microcrystalline silicon have been an area of vivid scientific interest.

It is generally acknowledged, that light-trapping capability is a key property of high-efficiency thin-film solar cells. Light-trapping means an increased optical absorption of thin film silicon solar cells. Together with industrial requirements for short deposition time this defines the main goals of all thin film silicon solar cell developments. A first ingredient for this development is the front transparent conductive oxide (TCO) layer of the solar cell and secondly—as will be shown herein later—the surface structure of the base substrate 10; more precise the texture of the interface between substrate 10 and front electrode 12 shown in FIG. 1.

A general disadvantage of this design is a trade off between the “optical thickness” of the absorber layer (which should be large in order to enhance absorption) and the distance between the electrodes—“electrical thickness”, which should be small to reduce the influence of the Staebler-Wronski effect on cell efficiency in a long term. In order to reduce the influence of the Staebler-Wronski effect on amorphous Si cells the generally accepted approach is to reduce the cell thickness. This however limits the ultimate cell efficiency even when deposited on a good quality light scattering TCO optimized for maximal light trapping in the subsequent Si layer. In order to increase current in a thin (less than 300 nm thick) amorphous silicon cell in tandem (multi-junction) devices, an intermediate reflector can be used. Finally, for further enhanced efficiency of tandem (micromorph) device, a relatively thick (around 2 microns) layer of microcrystalline Si is advantageous.

Light scattering properties of surface textured substrates have become an important issue in the process of optimization of thin-film solar cell performance. Light trapping in a tandem amorphous/microcrystalline silicon (a-Si/μc-Si) (Si-tandem) photovoltaic solar cells is advantageous for providing high quantum efficiency, since it not only leads to higher short circuit current (J_{sc}), but also allows thinner intrinsic silicon layers, especially a thinner μc-Si layer, which is particularly important for reducing the overall cost of making such solar cells. It is for these reasons and potentially huge market opportunities that light trapping in a-Si/μc-Si tandem photovoltaic solar cells attracts significant interest, as seen in the literature.

Light scattering also depends on the morphology of the transparent conductive oxide (TCO). Efficient light trapping in these thin-film solar cells is based on scattering of light at rough interfaces, which are introduced into solar cells by using superstrates and/or TCO with textured surfaces. Traditionally, Si-tandem solar cells have used a surface-textured TCO layer only, typically either ZnO or SnO₂ type. Due to insufficient light trapping, the μc-Si thickness is increased beyond 2 μm to obtain very high cell efficiency. The record Si-tandem cell efficiency is 11.7% by Kaneka (Osaka, Japan), a record that has remained untouched since 2004.

### SUMMARY

One embodiment is a thin film solar cell comprising:

a substrate comprising a textured surface comprising features; and

a front electrode layer comprising a transparent conductive oxide adjacent to the textured surface, wherein the electrode layer has an average thickness less than 1.5 times the average lateral feature size of the textured surface.

Another embodiment is a thin film solar cell comprising:

a substrate comprising a textured surface comprising features, wherein the average lateral feature size of the textured surface is 50 nm or greater, and wherein the cell has a stabilized efficiency of 11.5 percent or greater.

Another embodiment is an article comprising;

a glass substrate comprising a textured surface comprising features, wherein the textured surface has a RMS roughness in the range of from 250 nm to 3000 nm, and a correlation length in the range of from 2 μm to 6 μm.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is an illustration of a Prior Art tandem junction thin film silicon photovoltaic cell. (Thicknesses are not to scale.)

FIG. 2 is an illustration of a Prior Art PECVD plasma reactor.

FIG. 3 is an illustration of a tandem junction thin film silicon photovoltaic cell, according to one embodiment. Thicknesses are not to scale.

FIG. 4 is a plot of external quantum efficiency on flat and textured glass.

FIG. 5 is a plot of scatter ratio or haze for low (50-250 nm), medium (around 250-500 nm), medium-high (500-10000 nm) and high (>1000 nm) RMS roughness textured glass surfaces.

FIG. 6 is a plot of IV characteristics of a confirmed cell according to one embodiment.

FIG. 7 is a scanning electron microscope (SEM) image of a textured glass surface with a TCO disposed on the textured surface according to one embodiment.

FIG. 8 is a scanning electron microscope (SEM) image of a textured glass surface with a TCO disposed on the textured surface according to one embodiment.

FIG. 9 is a scanning electron microscope (SEM) image of a textured glass surface with a TCO disposed on the textured surface according to one embodiment.

FIG. 10 is a scanning electron microscope (SEM) image of a textured glass surface with a TCO disposed on the textured surface according to one embodiment.

FIG. 11 is an SEM image of an exemplary textured glass substrate made by a low temperature particle process.

FIG. 12A is a cross sectional illustration of a substrate comprising a textured surface.

FIG. 12B is a top down illustration of a substrate comprising a textured surface.

FIG. 13 is a top down microscope image of medium-high roughness substrates which shows the distribution of lateral feature sizes.

FIG. 14 is a graph summarizing the haze factors of different substrates as a function of the wavelength.

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

As used herein, the term “processing” includes any chemical, physical or mechanical effect acting on substrates. Substrates in the sense of this invention are components, parts or workpieces to be treated in a processing apparatus OR system. Substrates include but are not limited to flat, plate shaped parts having rectangular, square or circular shape. In one embodiment this invention addresses essentially planar substrates of a size >0.5 m², for example, >1 m², such as thin glass plates.

“A vacuum processing or vacuum treatment system or apparatus” as used herein comprises at least an enclosure for substrates to be treated under pressures lower than ambient atmospheric pressure.

As used herein, the term “Chemical Vapour Deposition (CVD)” is a well known technology allowing the deposition of layers on heated substrates. A usually liquid or gaseous precursor material is typically fed to a process system where a thermal reaction of said precursor results in deposition of said layer. LPCVD is a common term for low pressure CVD.

“Diethyl zinc (DEZ)” is a precursor material for the production of certain TCO layers in vacuum processing equipment.

“TCO” stands for “transparent conductive oxide”, “TCO layers” consequently are transparent conductive layers.

As used herein, the terms “layer, coating, deposit and film” are interchangeably used in this disclosure for a film deposited in vacuum processing equipment, be it CVD, LPCVD, plasma enhanced CVD (PECVD) or PVD (physical vapour deposition)

As used herein, the terms “solar cell or photovoltaic cell (PV cell)” are used to describe an electrical component, capable of transforming light (essentially sun light) directly into electrical energy by means of the photoelectric effect.

As used herein, the term “thin-film solar cell” in a generic sense includes, on a supporting substrate, a p-i-n junction established by a thin film deposition of semiconductor compounds, sandwiched between two electrodes or electrode layers. A p-i-n junction or thin-film photoelectric conversion unit includes an intrinsic semiconductor compound layer sandwiched between a p-doped and an n-doped semiconductor compound layer. The term “thin-film” indicates that the layers mentioned are being deposited as thin layers or films by processes like, PEVCD, CVD, PVD or alike. Thin layers essentially mean layers with a thickness of 10 μm or less, for example, less than 3 μm, for example, less than 2 μm.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

One embodiment is a thin film solar cell comprising:

a substrate comprising a textured surface comprising features; and

a front electrode layer comprising a transparent conductive oxide adjacent to the textured surface, wherein the electrode layer has an average thickness less than 1.5 times the average lateral feature size of the textured surface.

Another embodiment is a thin film solar cell comprising:

a substrate comprising a textured surface comprising features, wherein the average lateral feature size of the textured surface is 50 nm or greater, and wherein the cell has a stabilized efficiency of 11.5 percent or greater.

Another embodiment is an article comprising;

a glass substrate comprising a textured surface comprising features, wherein the textured surface has a RMS roughness in the range of from 250 nm to 3000 nm, and a correlation length in the range of from 2 μm to 6 μm, for example, 2 to 5 μm, for example, 2 to 4 μm, or, for example, greater than 2 to 6 μm, for example, greater than 2 to 5 μm, for example, greater than 2 to 4 μm. The article can be used in any of the embodiments of thin film solar cells described herein.

FIG. 12A is a cross sectional illustration of a substrate 11 comprising a textured surface 44. FIG. 12B is a top down illustration of a substrate 11 comprising a textured surface 44. The textured surface 44 comprises features 46. Average lateral feature size can be calculated by taking the sum of each of the feature sizes 48 divided by the number of features. Feature size, for example, for concave features is measured by longest lateral length of each feature such as the distance between local surface maxima 37. Feature size, for example, for convex features is measured by longest lateral length of each feature such as the distance between local surface minima 47 as shown in FIG. 10.

Although glass is the substrate of choice for the deposition of superstrate-type thin film silicon solar cells, little has been done so far on it to leverage the performances of the solar cells. In a joint research effort between Oerlikon Solar-Lab and Corning Incorporated, Micromorph tandem cells are developed on textured glass substrates. Here ZnO by LPCVD is studied as front TCO in combination with the texture of the glass substrates.

Surface textured substrates, for example, textured glass, are advantageous for, for example, thin TCO and μc-Si layers, improved light-trapping, and improved cell efficiency in thin-film multi-junction photovoltaic solar cells. Surface textured substrates, according to some embodiments, can be accomplished by either chemical-mechanical processes or fused particles on glass. Such substrates can provide an increase in light scattering from such textured surfaces which produces increased light trapping in, for example, Si-tandem silicon layers. Textured glass surfaces enable high efficiency Si-tandem cells with thin TCO and silicon layers, especially the μc-Si layer. A proper combination of the superstrate texture, the TCOs and thicknesses of the sub-cells of the Si-tandem cell leads to the higher cell efficiencies.) When combined with an intermediate reflector between the a-Si and μc-Si cells, the textured glass surface provides sufficient light trapping to reduce the μc-Si thickness to a practical thickness of less than or equal to 3 μm. a-SiGe:H alloys can also be as well positively affected by the light-trapping capabilities of the textured glass substrate. Examples of triple-junctions are a-Si/a-SiGe/a-SiGe, a-Si/a-SiGe/uc-Si and a-Si/uc-Si/uc-Si. Interlayers, for example, an intermediate reflector can be as well implemented in the different configurations, especially after the middle cells. Also, the glass texture can replace the texture that can be obtained by, for example, depositing a thick TCO and etching it by chemical or plasma means. The high efficiency cell with a textured superstrate can therefore be made with a practical LPCVD TCO thickness of <1.5 μm. The resulting stabilized cell efficiency can be >11.5%.

Surface texturing by means of either chemical-mechanical processes or fused particles on glass, causes an increased light scattering from such surfaces, which allows increased light trapping in Si-tandem silicon layers. However, we have also shown that, in some instances, there may be limits in the surface roughness that would benefit cell efficiency improvement. For example, surfaces with an increased roughness (e.g., with sharp features) might cause significant shunting of a solar cell. On the other hand, surfaces with a decreased roughness (e.g., more soft features), while still producing some light scattering, do not significantly improve cell efficiency. Furthermore, textured glass surfaces enable the fabrication of Si-tandem cells with thin TCO and silicon layers, especially a thin μc-Si layer. Moreover, Si-tandem cell layers, TCO, a-Si, and μc-Si, may get additional roughness when deposited on textured substrates, as their crystalline growth may be effected by textured substrates. A proper combination of textures and thicknesses of Si-tandem cell superstrates and layers leads to increased cell efficiencies.

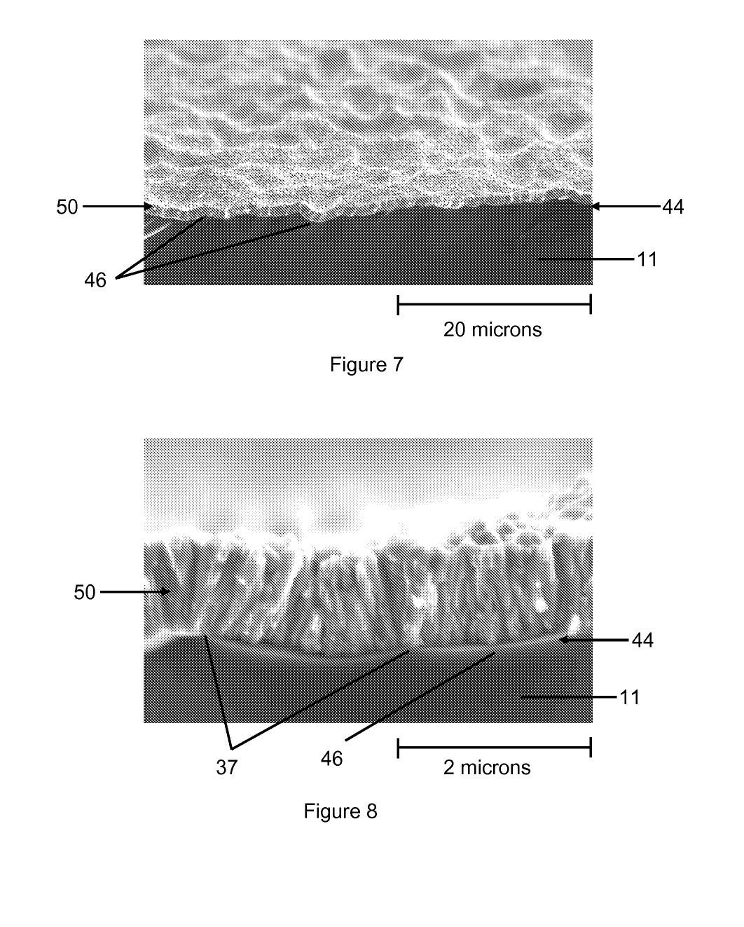

FIGS. 7 and 8 are scanning electron microscope (SEM) images of substrates 11 comprising a textured glass surface 44 comprising features 46 with a TCO 50 disposed on the textured surface according to one embodiment. The SEM in FIG. 7 is a 65 degree view of a lapped and etched substrate comprising a textured glass surface coated with a TCO comprising B-doped ZnO. FIG. 8 is a cross-sectional view SEM of a lapped and etched substrate comprising a textured glass surface coated with a TCO comprising B-doped ZnO.

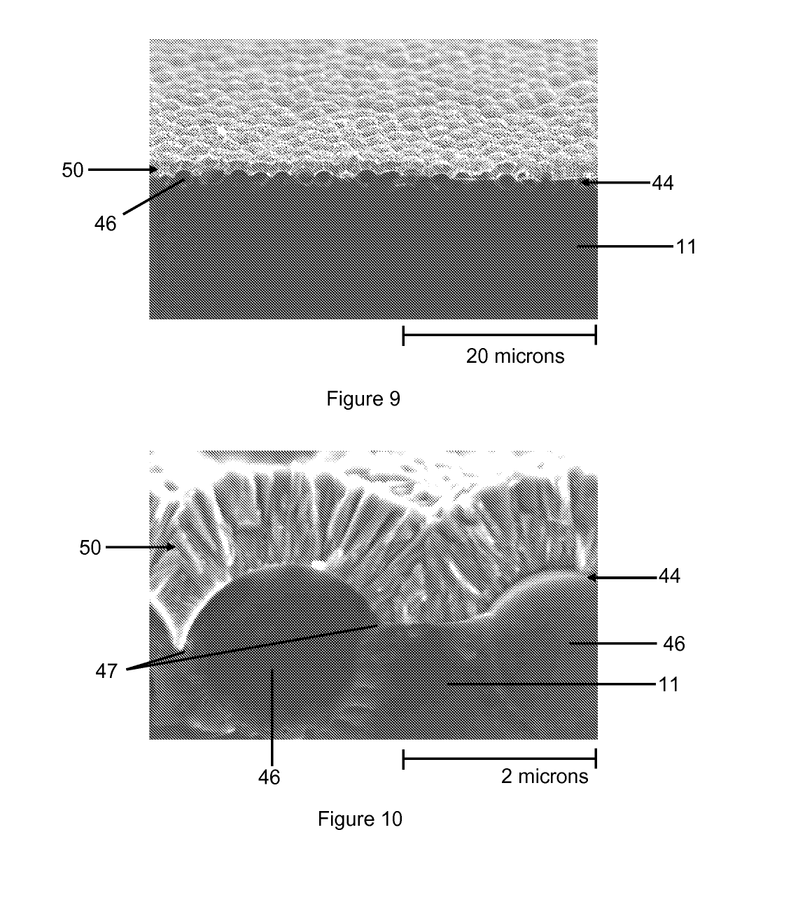

FIGS. 9 and 10 are scanning electron microscope (SEM) images of substrates 11 comprising a textured glass surface 44 comprising features 46 with a TCO 50 disposed on the textured surface according to one embodiment. The SEM in FIG. 9 is a 65 degree view of 2.5 μm silica particles on a soda lime substrate surface coated with a TCO comprising B-doped ZnO. FIG. 10 is a cross-sectional view SEM of textured glass substrates comprising fused particles according to one embodiment. In this embodiment, 2.5 micron silica particles were fused onto a soda lime substrate to create the textured surface. The textured surface was coated with a TCO comprising B-doped ZnO. Feature size, for example, for convex features is measured by longest lateral length of each feature such as the distance between local surface minima 47.

In one embodiment, the electrode layer has an average thickness less than 1.5 times the average lateral feature size of the textured surface. In some embodiments, there may be small features in addition to the majority of larger features. For example, in FIG. 8, the local maxima indicated by 37 are separated by ˜2 microns. In FIG. 10, the local surface minima indicated by 47 are separated by ˜3 microns. The thickness of the TCO is 1.2 microns which is less than the lateral feature sizes shown in the figures.

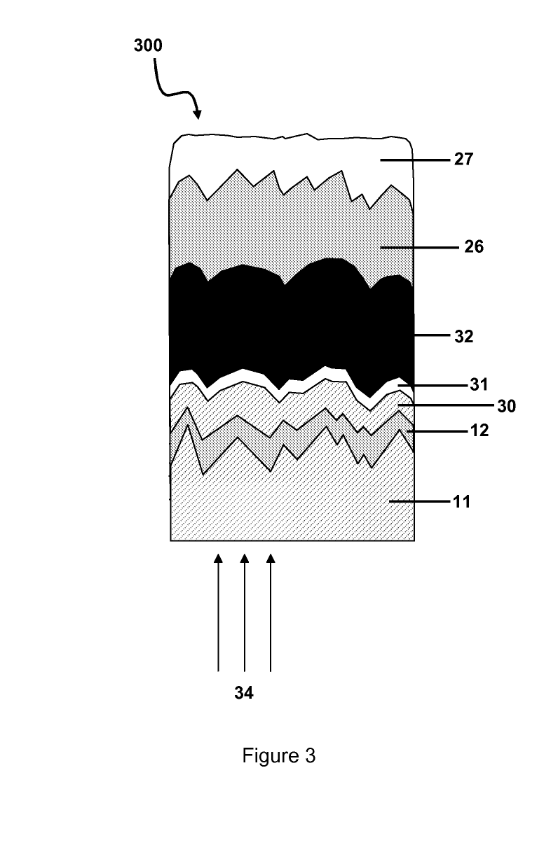

Features 300 of a tandem junction thin film solar cell, according to one embodiment, is shown in FIG. 3. The thin film solar cell comprises a substrate 11, preferably glass with a texture on the surface where, during manufacturing of the solar cell, the deposition of the functional layers 12, 30, 31, 32, 26, and 27 takes place. In other words, a textured side (surface) of (glass) substrate 11 acts as interface to the solar cell stacks 12, 30, 31, 32, 26, and 27. A front electrode layer 12 comprising a transparent and electrically conductive layer such as a TCO is applied to the substrate 11. A first stack of silicon compound layers, a p-i-n photovoltaic conversion unit or top cell 30, preferably with an amorphous silicon absorber, is applied on said front electrode layer 12. An interlayer 31 may be applied adjacent to said p-i-n-layer stack or top-cell 30. Further, a second p-i-n photovoltaic conversion unit or bottom cell 32 is stacked on interlayer 31 (if present, otherwise directly on top cell 30). The second p-i-n photovoltaic conversion unit or bottom cell 32 is preferably exhibiting a microcrystalline silicon absorber layer. A back electrode layer 26, again preferably a TCO, is arranged on top of the top cell 32. A further layer, a back contact 27 provides for reflecting light, which has not been absorbed by top or bottom cell, back into the layer stack. Other back contacts can be based on thin ZnO (50-100 nm) with >100 nm Ag/or Al, or multi layers of Ag/Al. This reflector can be specular or (preferred) diffuse and can be made from reflective metal layers, white paint, white foils or alike. Light, arrows 34 is typically incident from the side of the deposition substrate such that the substrate becomes a superstrate in the cell configuration.

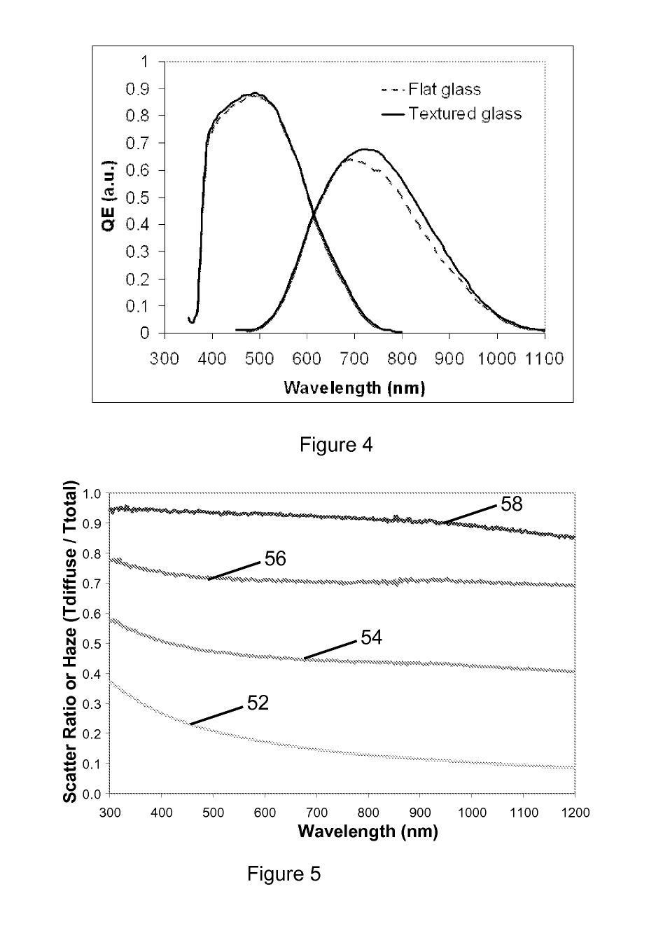

FIG. 4 represents the quantum efficiency (QE) curves of top and bottom cells on flat and textured glass substrates. The EQE is remarkably improved in the red to infrared region by the glass texture. This yields a bottom cell current improvement from 12.2 to 13.2 mA/cm² for the given same top cell in FIG. 4. Note that slight interference fringes present on flat substrates disappear on textured glass. In this experiment, the top and bottom cell thicknesses are 250 nm and 1200 nm, respectively. Despite the relatively thin bottom cell, the bottom cell current density—as estimated from the quantum efficiency—on the textured substrate is 13.2 mA/cm². This is 1 mA/cm² more or a considerable increase of 8.2% over the current density of the bottom cell on the flat glass substrate.

Further optimization of Micromorph solar cells on such textured glasses allows for devices with exceptional performances. A preferred embodiment or cell design was identified for the textured glass. It consists of a front ZnO layer of only 1.2 μm and has an intermediate reflector (interlayer) based on n-doped silicon oxide implemented. Further, no anti-reflection (AR) coating was incorporated in this device. This would normally be applied to the side of substrate 11 which is exposed to light. Such an AR could further improve the efficiency of the overall cell.

Degradation in cell performance with exposure to light is a well-known problem with solar cells using a-Si due to the Staebler-Wronski effect. The impact on the cell is that the cell efficiency decreases due to a decrease in fill-factor and a smaller decrease in short-circuit current density. The magnitude of the decrease is a function of a-Si thickness with thicker cells degrading more on a percentage basis than thinner cells. For this reason, a-Si cells are generally limited to thicknesses of <300 or preferably <250 nm. The effect is present in both single junction a-Si cells and tandem cells which include a-Si absorber layers. A typical test for stability is to subject the cell to an illumination of one sun for 1000 hours at a temperature of 50° C. A stabilized cell is defined to be a cell that has undergone this test condition.

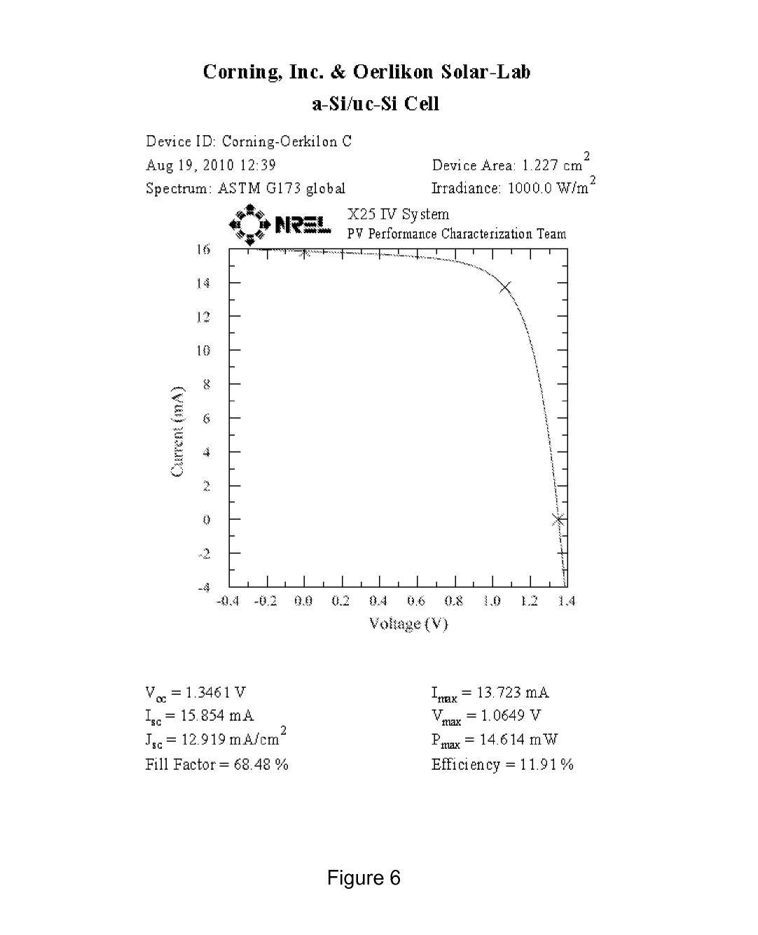

The initial and stabilized electrical parameters of the champion cell on a textured glass substrate are given in Table 1. The cell stabilizes after 1000 hours of light-soaking to 11.8% from 13.1% initial with a relative degradation of 10%. This cell has been sent to NREL for independent AM1.5 characterization and the J-V curve is given in FIG. 6.

TABLE 1

Measurement

| | Cell | Voc | FF | Jsc | Eff. |
|---|---|---|---|---|---|
| Lab | State | (mV) | (%) | (mA/cm²) | (%) |
| Oerlikon | Stable | 1361 | 71.40 | 12.15 | 11.80 |
| NREL | Stable | 1346 | 68.48 | 12.90 | 11.91 |

In FIG. 6, the J-V curve of a cell, according to one embodiment, is represented after 1000 hours of light-soaking at 50° C. The stabilized efficiency was measured in-house at 11.8%.

The cell was prepared with the following characteristics:
TCO front electrode layer: ZnO layer of 1.2 micron, sheet resistance above 5 and more preferably above 20 Ohm/square, could be realized alternatively from SnO₂ or other kinds of TCO.
Top cell, p-i-n amorphous silicon solar cell: 200 nm thick.
Intermediate reflector: 80 nm thick, based on n-doped silicon oxide deposited in KAI-M reactor.
Bottom cell, p-i-n microcrystalline silicon solar cell: 2.0 microns thick absorber layer, thinner absorbers could also be used with similar results; n-doped layer based on the same material as used for interlayer: n-doped silicon oxide, 200 nm thick, but thickness could be anything between 20 nm to 200 nm. The p-layer is made of microcrystalline silicon but could advantageously be replaced by p-doped silicon oxide, 10-50 nm thick.
The p and n layers are preferably realized as p and n-doped silicon oxides; layers based on the deposition parameters of p and n-doped microcrystalline silicon layers with the addition of a gas containing oxygen, preferably CO₂. (Only in p and n uc-SiO:H is CO₂ added) These layers are composed of at least the silicon oxide phase and a crystalline silicon phase. The presence of the latter can be evidenced by Raman spectroscopy.
Back contact: Undoped ZnO, 5.5 microns, sheet resistance above 20 Ohm/square, could be replaced with thinner layers with lower or more advantageously equivalent or higher sheet resistance based on ZnO, or metallic back contact e.g. based on Ag, Al or other suitable metal.
Textured glass substrate: prepared by a ground, lapped, and etched method. The best cell performance was obtained with medium-high roughness substrates as the substrates for the devices.

### EXAMPLES

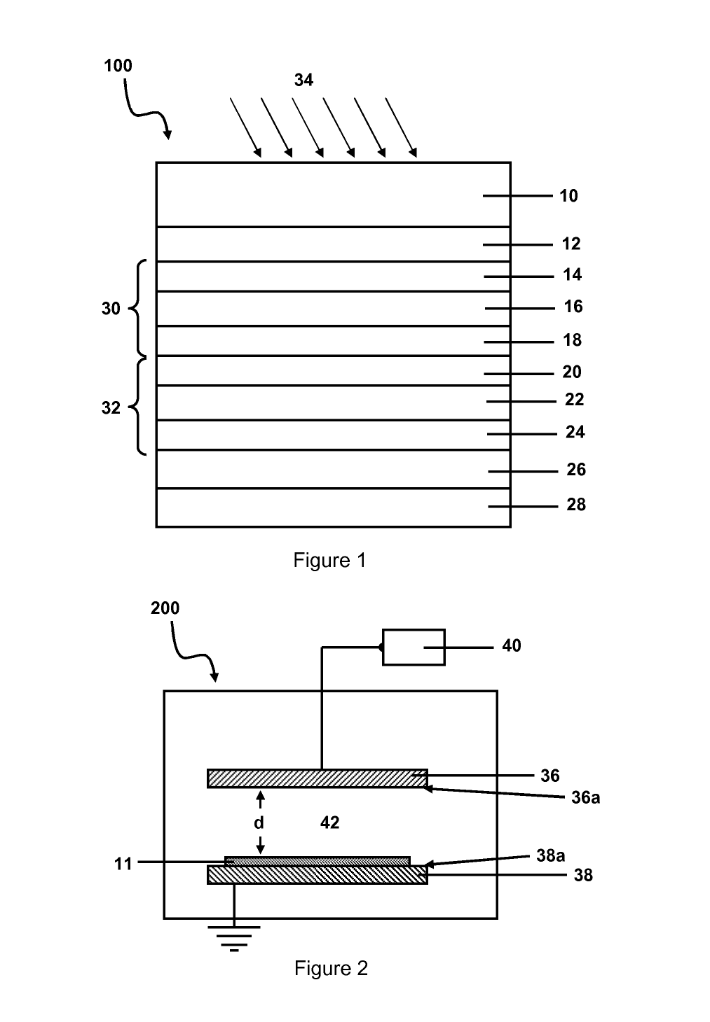

A thin-film silicon tandem junction, according to one embodiment, was manufactured by deposition by PECVD equipment known as an Oerlikon Solar KAI PECVD reactor. To improve deposition rates for solar-grade amorphous and microcrystalline silicon these reactors run with radio frequency (RF) power at a excitation frequency of 40.68 MHz. The results described below have been obtained in KAI-M (520×410 mm²) reactors. One focus had been laid on the further development of the front and back ZnO contact (=electrodes 12, 26 shown in FIG. 1) for optimized Micromorph cell efficiencies. These rough as-grown ZnO layers are deposited by low pressure chemical vapor deposition (LPCVD) from diethylzinc as precursor material. Such a LPCVD process and deposition system are described in U.S. Pat. No. 7,390,731 (incorporated herein by reference). The TCO roughness enhances the light-trapping within the active layers of the tandem cell. In one embodiment, the TCO comprises B-doped ZnO.

The PECVD processes used for the deposition of the silicon layer on textured substrates have been tuned. New p- and n-doped layers deposited in the KAI-M reactor allow improving the open-circuit voltage (Voc) and fill factor (FF) of the tandem cell on even rougher substrates.

A textured glass by Corning Incorporated has been used to improve the light-trapping and thus enhancing the performances of the cells. It also permits the reduction of the ZnO layer thickness and the microcrystalline silicon absorber layer saving deposition and cleaning time. The test cells were fully patterned to an area of approximately 1 cm². To evaluate the stabilized performance, the tandem cells were light-soaked at 50° C. under 1 sun illumination for 1000 hours. The solar cells were then characterized under AM 1.5 illumination delivered from double-source sun simulators.

Several different types of glasses were tested for suitability for the chemical-mechanical method of glass texturing for Si-tandem PV solar cells: EagleXG®, high purity fused silica (HPFS®) (registered trademarks of Corning Incorporated), soda-lime, specialty glass for CdTe solar cells, etc. Results show that some glasses are more suitable for chemical-mechanical surface polishing, lapping, grinding and etching processes than others. Due to the nature of mechanical abrading dependence on glass surface strength, textures made on some specialty high surface strength glasses show features that could not be made on traditional glasses such as soda-lime. These features are particularly favorable for light trapping and suitable for the growth of TCO/silicon layers.

The following are observations on exemplary textured glass substrates:
Low (50-200 nm), medium (200-500 nm) and high (0.5-10 μm) surface roughness were tested. Low glass surface roughness is not enough for sufficient light trapping. High glass surface roughness may cause cell shunting. Optimum surface roughness has high enough diffuse transmittance, but with less than 2 μm surface RMS roughness (less than fpm may be advantageous).
The TCO may be able to be optimized for different surface textures.
Devices were made with an intermediate layer (interlayer) for further improving the top Si cell and thus to facilitate proper cell balancing.
Intrinsic layers, TCO, a-Si and μc-Si, were made with the thinnest possible thicknesses, which may allow the highest stabilized efficiencies and the lowest manufacturing costs.

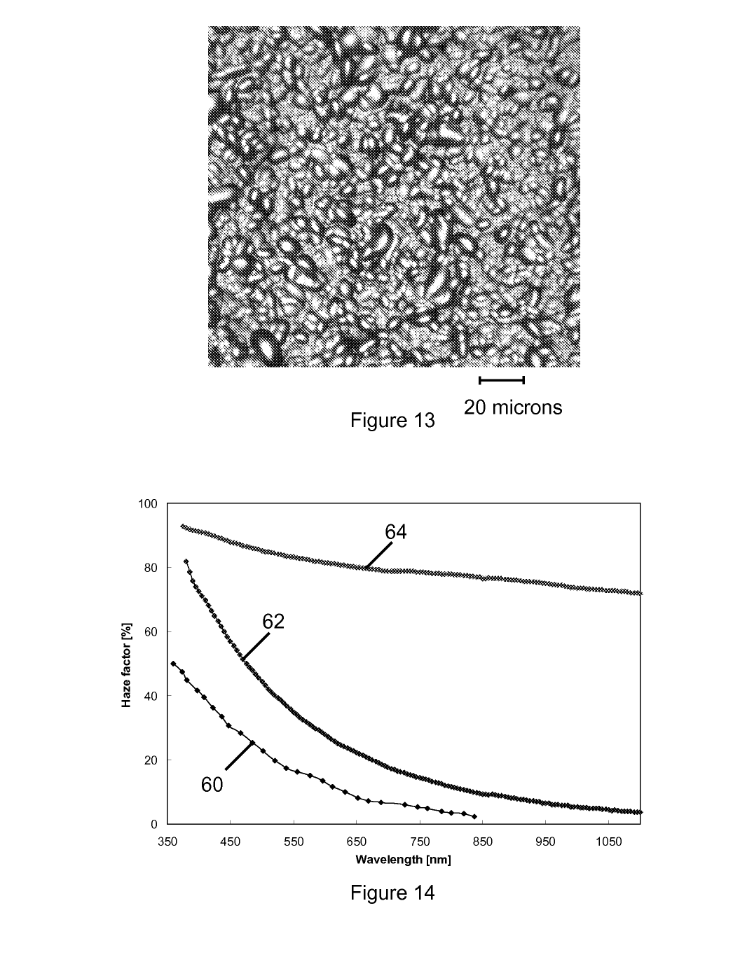

Chemical-mechanical textured glass substrates were fabricated using alumina abrasive particles on various grinding plates. After grinding, the ground surfaces of the substrates were etched in acid solution to remove micro-cracks that occur during the grinding process. Textured glass substrates with various surface RMS roughness were made, which were grouped in four categories: low (50-250 nm), medium (250-500 nm), medium-high (500-1000 nm) and high roughness (>1000 nm). The best cell performance was obtained with medium-high roughness substrates as the substrates for the devices. The textured substrates were fabricated by lapping on a lapping plate followed by an etching in 1:1:20 HF:HCl:H₂O. The surface roughness measured by AFM was ˜1 μm. FIG. 13 is a top down microscope image of medium-high roughness substrates which shows the distribution of lateral feature sizes. FIG. 5 is a plot of scatter ratio or haze for low (50-250 nm), line 52, medium (around 250-500 nm), line 54, medium-high (500-1000 nm), line 56, and high (>1000 nm), line 58, RMS roughness textured glass surfaces. Exemplary textured superstrates can provide high haze values, for example, 89% at 550 nm. Exemplary lapping and etching methods of making the substrates comprising textured surfaces are described in US Patent Application 2011/0126890 (incorporated herein by reference). Other exemplary methods of making the substrates comprising textured surfaces are described in U.S. Provisional Patent Application 61/490,306 (incorporated herein by reference).

Textured glass substrates comprising fused particles were fabricated by fusing particles onto/or partially into planar glass substrates. The processes used for fusing particles are split into two general categories: low temperature and high temperature particles. In the low temperature particle process, glass particles having lower softening point than the glass substrates are fused to the glass substrate by heating after formation of a monolayer of particles. In the high temperature particle process, glass or other high temperature particles are deposited on a lower softening point glass substrate that is heated allowing the particles to attach to the surface of the substrate. A large number of particle/substrate combinations have been explored. Within each type, the lateral feature size and surface roughness are controlled by a combination of particle size and process temperature. As with the chemical mechanical process, samples with very low surface roughness do not show enhanced cell performance and samples with high surface roughness exhibit electrical degradation. Exemplary methods of making the substrates comprising textured surfaces comprising particles are described in U.S. patent application Ser. No. 13/033,175 (incorporated herein by reference). Other exemplary methods of making the substrates comprising textured surfaces comprising particles are described in U.S. patent application Ser. No. 12/517,331 (incorporated herein by reference).

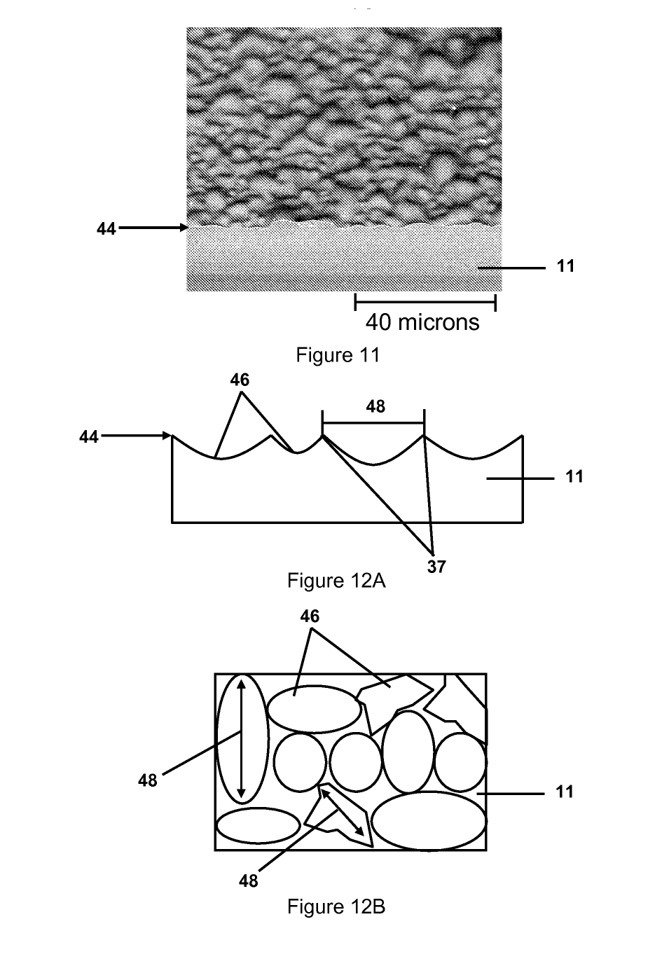

The best cell performance for the low temperature particle process was obtained with alkali silicate glass particles on a soda lime substrate. The particles had a median size of 3.4 μm and the substrate was heated to a temperature of 620° C.-650° C. The glass substrate 11 comprises a textured surface 44 having an RMS roughness of 690 nm and a correlation length of 3.9 μm. An SEM image is shown in FIG. 11. According to one embodiment, the textured surface has a RMS roughness in the range of from 250 nm to 3000 nm, for example, 500 nm to 3000 nm, for example, 500 nm to 2000 nm, for example, 500 nm to 1000 nm, or for example, 250 nm to 1000 nm and/or a correlation length in the range of from 2 to 6 μm, for example, 2 to 5 μm, for example, 2 to 4 μm, or, for example, greater than 2 to 6 μm, for example, greater than 2 to 5 μm, for example, greater than 2 to 4 μm. The textured surface can comprise concave, convex, or a combination of convex and concave features.

The best cell performance for the high temperature particle process was obtained with silica glass particles on a soda lime substrate. The silica particles were 2.5 μm and the substrate was heated to a temperature of 700° C.-740° C. The Si-tandem cells made with particles on glass did not include the interlayer and were not fully optimized.

FIG. 14 is a graph summarizing the haze factors of different substrates as a function of the wavelength. The haze factor is defined as the ratio of the diffuse and the total optical transmission. The line 60 represents the haze factor of the high quality “commercially” available SnO₂ TCO which in general is applied by R&D groups to obtain highest cell efficiencies. A typical in-house LPCVD ZnO deposited on flat borofloat glass, line 62 results in an already considerably higher haze factor over the whole measured wavelength range as compared to the commercially available type SnO₂ and demonstrates the high light-trapping potential of this TCO.

The additional implementation of the textured glass boosts the haze factor, line 64, further to values of 75% to 85% especially in the wavelength range where the microcrystalline cell possesses a spectral response. This is at least a 4-5 times higher haze factor than typical LPCVD ZnO on flat glass and at least 8-10 times higher than the commercially available TCO based on SnO₂ indicating the extremely scattering potential of the combination textured glass and LPCVD ZnO.

The thin film solar cell can comprise a substrate comprising a textured surface comprising features, and a front electrode layer comprising a transparent conductive oxide adjacent to the textured surface, wherein the electrode layer has an average thickness less than 1.5 times the average lateral feature size of the textured surface. The thin film solar cell can comprise a substrate comprising a textured surface comprising features, wherein the average lateral feature size of the textured surface is 50 nm or greater, and wherein the cell has a stabilized efficiency of 11.5 percent or greater. The article or the light scattering substrate can comprise a glass substrate comprising a textured surface comprising features, wherein the textured surface has a RMS roughness in the range of from 250 nm to 3000 nm, or a correlation length in the range of from 2 μm to 6 μm or both. The front electrode layer can have an average thickness less than the average lateral feature size of the textured surface. The substrate can be glass. The transparent conductive oxide can be disposed on the textured surface. The cell can further comprise a first p-i-n photovoltaic conversion unit adjacent to the electrode layer. The first p-i-n photovoltaic conversion unit can be disposed on the electrode layer. The first p-i-n photovoltaic conversion unit can comprise an amorphous silicon absorber. The amorphous silicon absorber can have a thickness less than 250 nanometers. The cell can further comprise a second p-i-n photovoltaic conversion unit adjacent to the first p-i-n photovoltaic conversion unit. The cell can further comprise an interlayer adjacent to the first p-i-n photovoltaic conversion unit. The cell can further comprise a back electrode layer comprising a transparent conductive oxide adjacent to the second p-i-n photovoltaic conversion unit. The cell can further comprise a second p-i-n photovoltaic conversion unit adjacent to the interlayer. The second p-i-n photovoltaic conversion unit can be disposed on the interlayer. The second p-i-n photovoltaic conversion unit can be disposed on the first p-i-n photovoltaic conversion unit. The cell can further comprise a back electrode layer comprising a transparent conductive oxide adjacent to the second p-i-n photovoltaic conversion unit. The second p-i-n photovoltaic conversion unit can comprise a microcrystalline silicon absorber. The cell can further comprise a reflector adjacent to the back electrode layer. The back electrode layer can be disposed on the second p-i-n photovoltaic conversion unit. The microcrystalline silicon absorber can have an average thickness of 2.5 microns or less. The microcrystalline silicon absorber can have an average thickness of 2.0 microns or less. The front electrode layer can have an average thickness of 1.5 microns or less. The front electrode layer can be deposited by chemical vapor deposition. The front electrode layer can comprise ZnO. The textured surface can have a roughness of from 200 nm to 3 microns. The cell can have a stabilized efficiency of 11.5 percent or greater. The cell can have a stabilized efficiency of greater than 11.7 percent. The average lateral feature size of the textured surface can be approximately 1 micron or greater. The cell can further comprise a front electrode layer comprising a transparent conductive oxide adjacent to the textured surface, wherein the electrode layer has an average thickness less than 1.5 times the average lateral feature size of the textured surface.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A thin film solar cell comprising:
a substrate comprising a textured surface comprising features; and
a front electrode layer comprising a transparent conductive oxide adjacent to the textured surface, wherein the electrode layer has an average thickness less than 1.5 times the average lateral feature size of the textured surface.

2. The cell according to claim 1, wherein the front electrode layer has an average thickness less than the average lateral feature size of the textured surface.

3. The cell according to claim 1, wherein the substrate comprises glass.

4. The cell according to claim 1, wherein the transparent conductive oxide disposed on the textured surface.

5. The cell according to claim 1, further comprising a first p-i-n photovoltaic conversion unit adjacent to the electrode layer.

6. The cell according to claim 5, wherein the first p-i-n photovoltaic conversion unit is disposed on the electrode layer.

7. The cell according to claims 5, wherein the first p-i-n photovoltaic conversion unit comprises an amorphous silicon absorber.

8. The cell according to claim 7, wherein the amorphous silicon absorber has a thickness less than 250 nanometers.

9. The cell according to claim 5, further comprising a second p-i-n photovoltaic conversion unit adjacent to the first p-i-n photovoltaic conversion unit.

10. The cell according to claim 1, further comprising an interlayer adjacent to the first p-i-n photovoltaic conversion unit.

11. The cell according to claim 10, further comprising a back electrode layer comprising a transparent conductive oxide adjacent to the second p-i-n photovoltaic conversion unit.

12. The cell according to claim 10, further comprising a second p-i-n photovoltaic conversion unit adjacent to the interlayer.

13. The cell according to claim 12, wherein the second p-i-n photovoltaic conversion unit is disposed on the interlayer.

14. The cell according to claim 12, wherein the second p-i-n photovoltaic conversion unit is disposed on the first p-i-n photovoltaic conversion unit.

15. The cell according to claim 14, further comprising a back electrode layer comprising a transparent conductive oxide adjacent to the second p-i-n photovoltaic conversion unit.

16. The cell according to claim 12, wherein the second p-i-n photovoltaic conversion unit comprises microcrystalline silicon absorber.

17. The cell according to claim 16, further comprising a reflector adjacent to the back electrode layer.

18. The cell according to claim 16, wherein the back electrode layer is disposed on the second p-i-n photovoltaic conversion unit.

19. The cell according to claim 16, wherein the microcrystalline silicon absorber has an average thickness of 2.5 microns or less.

20. The cell according to claim 19, wherein the microcrystalline silicon absorber has an average thickness of 2.0 microns or less.

21. The cell according to claim 1, wherein the front electrode layer has an average thickness of 1.5 microns or less.

22. The cell according to claim 1, wherein the front electrode layer is deposited by chemical vapor deposition.

23. The cell according to claims 1, wherein the front electrode layer comprises ZnO.

24. The cell according to claim 1, wherein the textured surface has a roughness of from 200 nm to 3 microns.

25. The cell according to claim 1, wherein the cell has a stabilized efficiency of 11.5 percent or greater.

26. The cell according to claim 25, wherein the cell has a stabilized efficiency of greater than 11.7 percent.

27. A thin film solar cell comprising:
a substrate comprising a textured surface comprising features, wherein the average lateral feature size of the textured surface is 50 nm or greater, and wherein the cell has a stabilized efficiency of 11.5 percent or greater.

28. The cell according to claim 27, wherein the cell has a stabilized efficiency of greater than 11.7 percent.

29. The cell according to claim 27, wherein the average lateral feature size of the textured surface is approximately 1 micron or greater.

30. The cell according to claim 27, further comprising a front electrode layer comprising a transparent conductive oxide adjacent to the textured surface, wherein the electrode layer has an average thickness less than 1.5 times the average lateral feature size of the textured surface.

31. An article comprising;
a glass substrate comprising a textured surface comprising features, wherein the textured surface has a RMS roughness in the range of from 250 nm to 3000 nm, and a correlation length in the range of from 2 μm to 6 μm.

32. A thin film solar cell comprising the article according to claim 31.

33. A thin film solar cell according to claim 32, wherein the cell has a stabilized efficiency of 11.5 percent or greater.
